(19) United States
(12) Patent Application Publication
(10) Pub. No.: US 2026/0164708 A1
(43) Pub. Date: Jun. 11, 2026

(54) POWER SEMICONDUCTOR DEVICE AND METHOD FOR MANUFACTURING SAME

(71) Applicant: Silergy Semiconductor Technology (Hangzhou) LTD, Hangzhou (CN)

(72) Inventors: Hui Yu, Hangzhou (CN); Jun Cai, Hangzhou (CN)

(21) Appl. No.: 19/355,100

(22) Filed: Oct. 10, 2025

(30) Foreign Application Priority Data
Oct. 18, 2024 (CN) 202411463012.8

(51) Int. Cl. H10D 30/65; H10D 30/01; H10D 62/10; H10D 62/60; H10D 64/27

(52) U.S. Cl. CPC H10D 30/658; H10D 30/0289; H10D 62/103; H10D 62/124; H10D 62/60; H10D 64/516; H10D 64/518

(57) ABSTRACT

A power semiconductor device can include: a substrate, including an active region having a source region and a drain region each of a first doping type and extending from an upper surface of the substrate into an interior thereof; a gate trench, formed between the source region and the drain region and being recessed from the upper surface of the substrate to the active region; a main gate located in the gate trench, where the main gate extends downward from an upper surface of the gate trench; and an insulating layer, formed between an inner wall of the gate trench and the main gate.

### RELATED APPLICATIONS

This application claims the benefit of Chinese Patent Application No. 202411463012.8, filed on Oct. 18, 2024, which is incorporated herein by reference in its entirety.

### FIELD OF THE INVENTION

The present invention generally relates to the field of semiconductor technology, and more particularly to power semiconductor devices and methods of making power semiconductor devices.

### BACKGROUND

A switched-mode power supply (SMPS), or a “switching” power supply, can include a power stage circuit and a control circuit. When there is an input voltage, the control circuit can consider internal parameters and external load changes, and may regulate the on/off times of the switch system in the power stage circuit. Switching power supplies have a wide variety of applications in modern electronics. For example, switching power supplies can be used to drive light-emitting diode (LED) loads. Power switches can be semiconducting devices, including metal-oxide-semiconductor field-effect transistors (MOSFETs) and insulated gate bipolar transistors (IGBTs), among others. For example, laterally-diffused metal-oxide-semiconductor (LDMOS) devices are widely used in such on-off type regulators.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a cross-section diagram of an example current power semiconductor device.

FIG. 2 is a diagram showing an example electric field distribution of the example power semiconductor device shown in FIG. 1.

FIG. 3 is a cross-section diagram of a first example power semiconductor device, in accordance with embodiments of the present invention.

FIG. 4 is a schematic diagram showing an example electric field distribution of the example power semiconductor device shown in FIG. 3.

FIG. 5 is a cross-section diagram of a second example power semiconductor device, in accordance with embodiments of the present invention.

FIG. 6 is a cross-section diagram of a third example power semiconductor device, in accordance with embodiments of the present invention.

FIG. 7 is a cross-section diagram of a fourth example power semiconductor device, in accordance with embodiments of the present invention.

FIG. 8 is cross-section diagram of a fifth example power semiconductor device, in accordance with embodiments of the present invention.

FIG. 9 is a cross-section diagram of a sixth example power semiconductor device, in accordance with embodiments of the present invention.

FIG. 10 is a cross-section diagram of a seventh example power semiconductor device, in accordance with embodiments of the present invention.

FIG. 11 is a cross-section diagram of an eighth example power semiconductor device, in accordance with embodiments of the present invention.

FIG. 12 is cross-section diagram of a ninth example a power semiconductor device, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Further, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

Semiconductor devices are generally manufactured using two complex manufacturing processes: front-end manufacturing and back-end manufacturing. Front-end manufacturing may involve the formation of a plurality of die on the surface of a semiconductor wafer. Each die on the wafer may contain active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components can be formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. The portion of the photoresist pattern subjected to light is removed using a solvent, exposing portions of the underlying layer to be patterned. The remainder of the photoresist may be removed, leaving behind a patterned layer. Alternatively, some types of materials can be patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface may be used to produce smaller and more densely packed active and passive components. Planarization can be used to remove material from the surface of the wafer and produce a uniformly flat surface. Planarization can involve polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer may be singulated using a laser cutting tool or saw blade. After singulation, the individual die can be mounted to a package substrate that can include pins or contact pads for interconnection with other system components. Contact pads formed over the semiconductor die can then be connected to contact pads within the package. The electrical connections can be made with solder bumps, stud bumps, conductive paste, or wire bonds, as a few examples. An encapsulant or other molding material may be deposited over the package to provide physical support and electrical isolation. The finished package can then be inserted into an electrical system and the functionality of the semiconductor device is made available to the other system components.

Power semiconductor devices, also referred to as power electronic components, are high-power electronic units primarily utilized in electrical equipment for energy conversion and control circuitry. In applications that demand high current and high-frequency switching, it can be essential to adopt devices with low gate charge (Qg) and strong robustness to ensure high efficiency in compact designs. Typically, these devices feature a source, a drain, and a main gate electrode, with the main gate positioned between the source and drain. When a voltage is applied to the main gate, it enables conduction between the source and drain electrodes. However, to meet the required breakdown voltage (BV), the source and drain must be spaced a certain distance apart, which imposes limits on how much the overall device size can be scaled down.

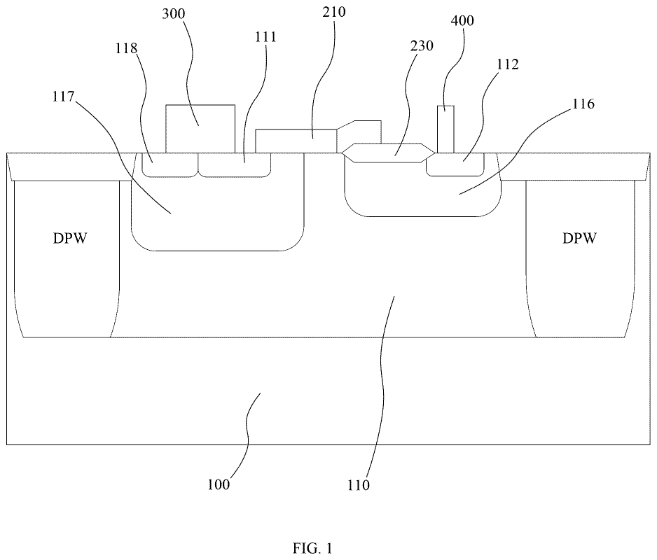

Referring now to FIG. 1, shown is a cross-section diagram of an example current power semiconductor device. In this example, the power semiconductor device can include source (or source electrode) 300, drain (or drain electrode) 400, and main gate (or main gate electrode) 210, respectively disposed on substrate 100 (bulk silicon), with main gate electrode 210 located between source electrode 300 and drain electrode 400. Source electrode 300 can electrically connect to source region 111 formed in substrate 100, and drain electrode 400 can electrically connect to drain region 112 formed in the substrate. A lateral drift region may be formed between source region 111 and drain region 112. When a voltage is applied to main gate electrode 210, conduction between source electrode 300 and drain electrode 400 can be enabled.

Power semiconductor devices may address requirements across analog, low-voltage digital, and high-voltage power domains. For analog applications, it can be essential to develop devices with enhanced analog precision. Digital complementary metal-oxide-semiconductor (CMOS) scaling has benefited from advances in lithography. However, from the perspective of process node scaling, lateral high-voltage (HV) and power devices are constrained by lateral geometry scaling under constant electric field conditions. This constraint implies that, at a target BV, the power semiconductor device may be limited by the peak electric field in bulk silicon, thus preventing size reduction in line with advanced process nodes.

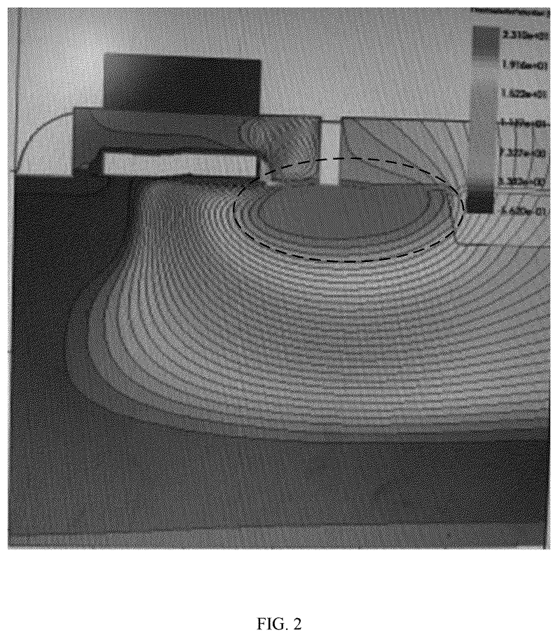

Referring now to FIG. 2, shown is a diagram showing an example electric field distribution of the example power semiconductor device shown in FIG. 1. In this example, the length of the lateral drift region in this power semiconductor device is relatively short, and the electric field reaches its maximum in the drain region of the bulk silicon (the region enclosed by the dashed lines), resulting in a lower breakdown voltage (BV) of the device and an increased risk of electrical breakdown.

In forming a gate trench in the substrate, positioning the main gate electrode within the trench rather than on the substrate surface, and filling the gate trench to form a thick insulating layer (e.g., an oxide layer), a higher peak electric field may result as compared to bulk silicon, the device's voltage withstand capability can be significantly enhanced. In this case, the drift region length may be transformed from the lateral spacing between the source and drain regions to the perimeter of the gate trench. This can structurally reduce the device's lateral dimension while maintaining the target breakdown voltage.

In particular embodiments, the gate trench may be formed in the substrate, and the main gate electrode can be embedded within the gate trench, and extending downward from the upper surface of the gate trench. The remaining volume of the gate trench may be filled to form the insulating layer. By leveraging the high peak electric field of the insulating layer, the device can achieve an improved breakdown performance. The drift region length can be limited by the trench perimeter rather than lateral spacing between the source and drain regions, thereby reducing the lateral footprint of the drift region at a given BV, and resulting in a more compact device structure and lower specific on-resistance (Rsp).

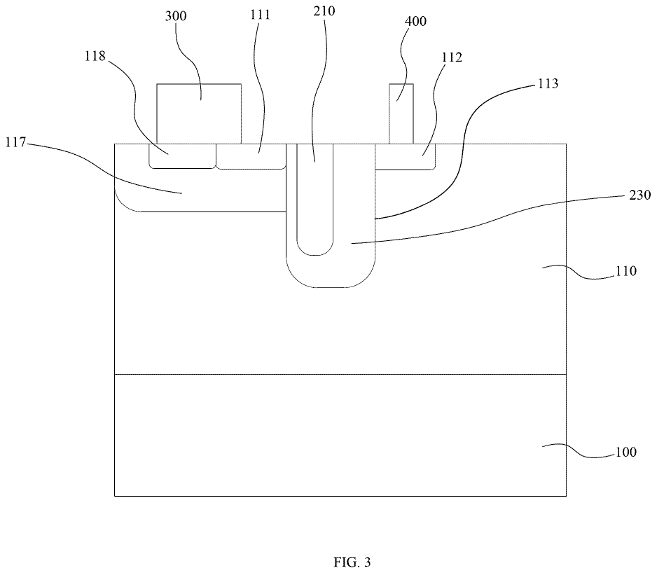

Referring now to FIGS. 3-8, shown are cross-section diagrams of example power semiconductor devices, in accordance with embodiments of the present invention. In these particular examples, power semiconductor device can include substrate 100, main gate 210, and insulating layer 230. Substrate 100 can include active region 110, which can include source region 111 and drain region 112, both of which being a first doping type and extending from an upper surface of substrate 100 into its interior. Gate trench 113 can be formed between source region 111 and drain region 112, and may be recessed from the upper surface of substrate 100 to active region 110. Main gate 210 can be located in gate trench 113, and main gate 210 may extend downward from an upper surface of gate trench 113. Insulating layer 230 can be formed between an inner wall of gate trench 113 and main gate 210.

The power semiconductor device may be a laterally-diffused metal-oxide-semiconductor (LDMOS) device, such as an NLDMOS or a PLDMOS. Source region 111 and drain region 112 may have the same ion doping type. As an example, when the power semiconductor device is an NLDMOS, N-type impurities can be doped in source region 111 and drain region 112, respectively. Similarly, when the power semiconductor device is a PLDMOS, P-type impurities can be doped in source region 111 and drain region 112, respectively. The following description primarily uses an NLDMOS power semiconductor device as an example for illustration purposes only, but any suitable type of power device can be supported in certain embodiments.

For example, substrate 100 may be a P-type substrate, and the thickness of substrate 100 can be adjusted as needed. An epitaxial layer may or may not be formed on substrate 100. When an epitaxial layer is present on substrate 100, the epitaxial layer may be either P-type or N-type, and active region 110 may be formed on the epitaxial layer. The main portion of active region 110 may be an N-type well (NWELL), which can be formed by doping N-type impurities into substrate 100. Source region 111 and drain region 112 may be formed by doping upper portions of substrate 100, with ion doping concentrations of source region 111 and drain region 112 being higher than that of active region 110.

As an example, gate trench 113 can be formed using thermal processing and advanced etching techniques, including anisotropic, isotropic, or a combination of both etching methods in varying proportions. Gate trench 113 can be recessed from the upper surface of substrate 100 to active region 110; that is, an opening of gate trench 113 may be located on the upper surface of substrate 100. The perimeter of gate trench 113 can restrict the length of the drift region between source region 111 and drain region 112, thereby ensuring the BV of the power semiconductor device. At a target BV, the lateral dimension of the power semiconductor device can be reduced while reducing the Rsp of the power semiconductor device. The width of gate trench 113 can be linearly scaled down as the process node advances. The width, depth, and perimeter design of gate trench 113 may depend on achieving the optimal trade-off between BV and Rsp within the constraints of minimal area.

Optionally, insulating layer 230 may include a gate oxide, and main gate 210 may include a polysilicon or a conductive metal deposited on the gate oxide. The gate oxide can be in contact with the source region. A thickness of the gate oxide may be adjusted as needed, e.g., in a range from about 20 angstroms to about 400 angstroms. Main gate 210 may extend downward from the upper surface of gate trench 113; that is, a top end of main gate 210 can be located on the upper surface of gate trench 113. The top end of main gate 210 can be connected to an external circuit.

For example, insulating layer 230 can be made of silicon dioxide. A dielectric constant of insulating layer 230 may be greater than a dielectric constant of substrate 100 (e.g., bulk silicon), and under the same withstand voltage requirement, the required width of insulating layer 230 may be smaller than that of the bulk silicon. Main gate 210 can be arranged at a location closer to source region 111 than to drain region 112, such that a thickness of insulating layer 230 between main gate 210 and drain region 112 is relatively large, and insulating layer 230 can sufficiently withstand voltage.

In particular embodiments, gate trench 113 can be formed between source region 111 and drain region 112, and may be recessed from the upper surface of substrate 100 to active region 110. Main gate 210 can be located in gate trench 113, and main gate 210 may extend downward from the upper surface of gate trench 113. Insulating layer 230 can be formed between the inner wall of gate trench 113 and main gate 210. Thus, in this example, the drift region length can be transformed from the lateral spacing between the source and drain regions to the perimeter of the gate trench. This structural shift may reduce the device's lateral dimension while maintaining the target BV, and lowering the Rsp, thereby resulting in an improved BV-to-Rsp trade-off and enabling a more compact device design.

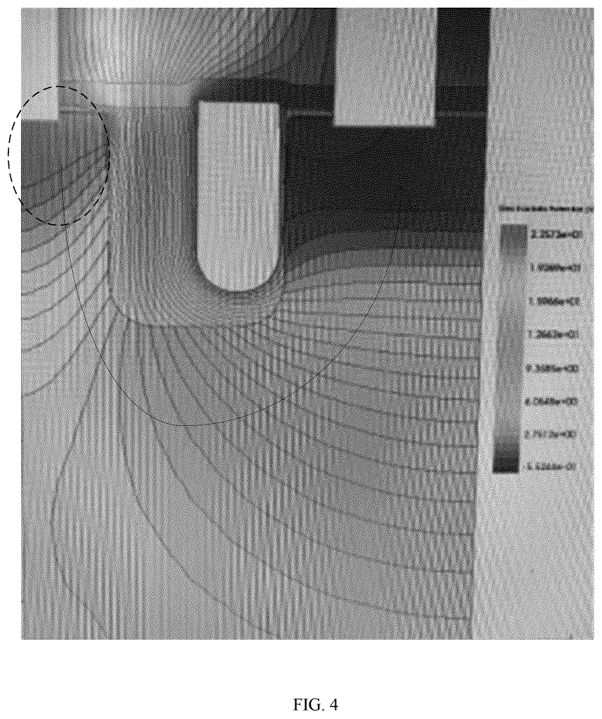

Referring now to FIG. 4, shown is a schematic diagram showing an example electric field distribution of the example power semiconductor device shown in FIG. 3. In this particular example, the electric field may gradually decrease along the direction of the arrow, while the region enclosed by the dashed lines may exhibit the highest field intensity, and the thick insulating layer filling the gate trench can withstand a larger electric field, thereby increasing the breakdown voltage of the device.

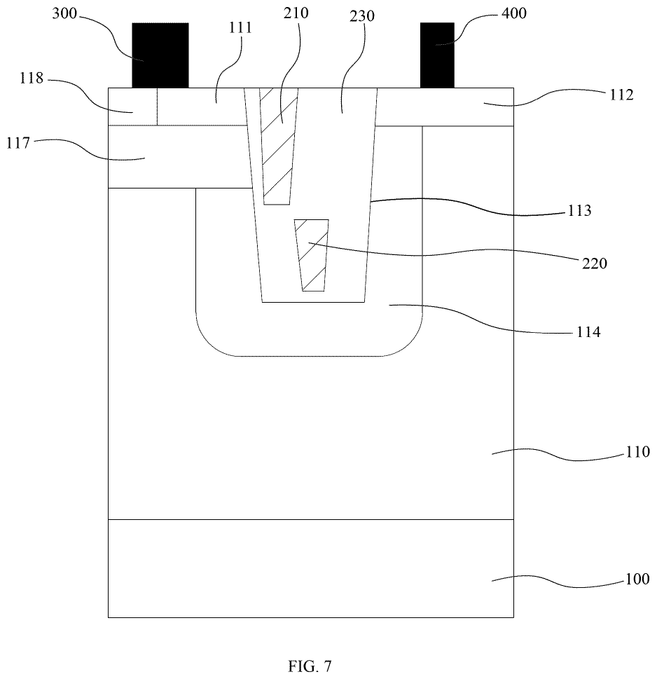

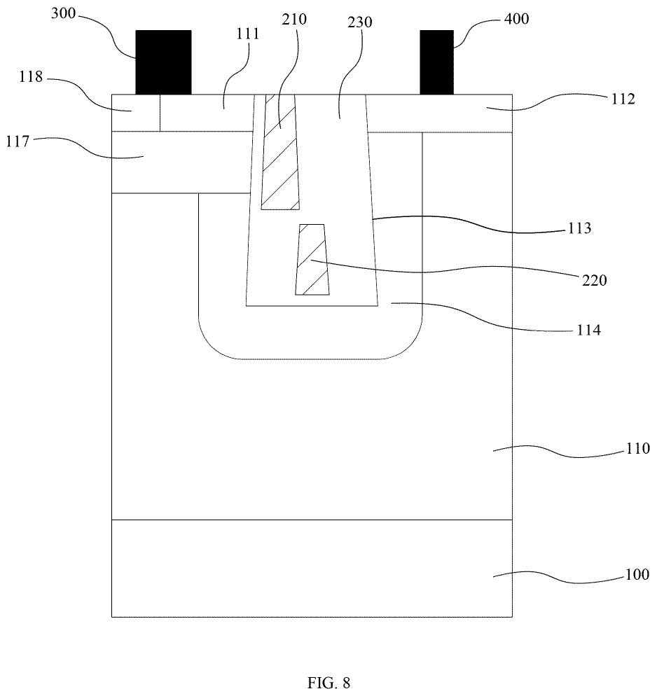

As shown in FIGS. 3-8, a cross section of gate trench 113 can be, e.g., U-shaped, rectangular, or trapezoidal. When the cross section of gate trench 113 is U-shaped, the opening of the U-shaped gate trench 113 may be located on the upper surface of substrate 100. When the cross section of gate trench 113 is trapezoidal, the opening of the trapezoid gate trench 113 can be located on the upper surface of substrate 100. As shown in FIG. 7, the opening of the trapezoid gate trench 113 may correspond to the top base of the trapezoid, and the length of the top base may be greater than the length of the bottom base of the trapezoid. In the example shown in FIG. 8, the length of the top base may instead be smaller than the length of the bottom base. Through such arrangements, the effective length of the drift region can be extended.

As shown in FIGS. 3-8, main gate 210 can be arranged at a location closer to source region 111 than to drain region 112. That is, the distance between main gate 210 and source region 111 can be less than the distance between main gate 210 and drain region 112. The inner wall of gate trench 113 can include a first inner wall positioned closer to source region 111 and a second inner wall positioned closer to drain region 112. The distance between main gate 210 and the second inner wall of gate trench 113, referred to as Distance A, can be adjusted as needed. Disposing main gate 210 closer to source region 111 can better control the current flow from source region 111 to drain region 112, which can help to improve the control of carrier transmission in the channel, thereby improving the switching characteristics and reducing the on-resistance. Main gate 210 may be positioned closer to source region 111, which can help reduce parasitic capacitance between main gate 210 and drain region 112 to some extent.

In particular embodiments, the power semiconductor device can also include source electrode 300 and drain electrode 400. Source electrode 300 can be disposed on the upper surface of substrate 100 and electrically connected to source region 111. Drain electrode 400 can be disposed on the upper surface of substrate 100 and electrically connected to drain region 112. As shown in FIG. 3, a bottom of source electrode 300 can connect to source region 111 to achieve electrical conduction between source electrode 300 and source region 111, and a bottom of drain electrode 400 can connect to drain region 112 to achieve electrical conduction between the drain 400 and drain region 112. The power semiconductor device can be connected to the external circuit through source 300 and drain 400.

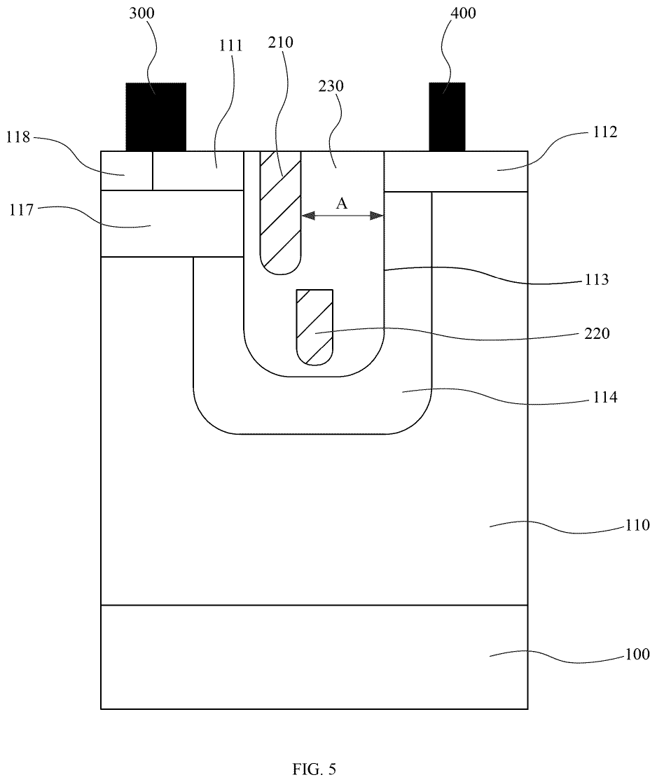

As shown in FIGS. 5-8, the power semiconductor device can also include at least one shielding gate 220, which can be disposed in gate trench 113. Shielding gate 220 may be disposed below main gate 210, and shielding gate 220 and main gate 210 can be spaced apart from each other. Shielding gate 220 can be disposed at a side of main gate 210 that is closer to drain region 112. Main gate 210 can control the channel of the power semiconductor device, while shielding gate 220 can shield the electric field generated by the high voltage at drain 400. For example, main gate 210 and shielding gate 220 can be arranged in an interleaved manner, with insulating layer 230 formed therebetween. In one example, shielding gate 220 can be made of conductive materials.

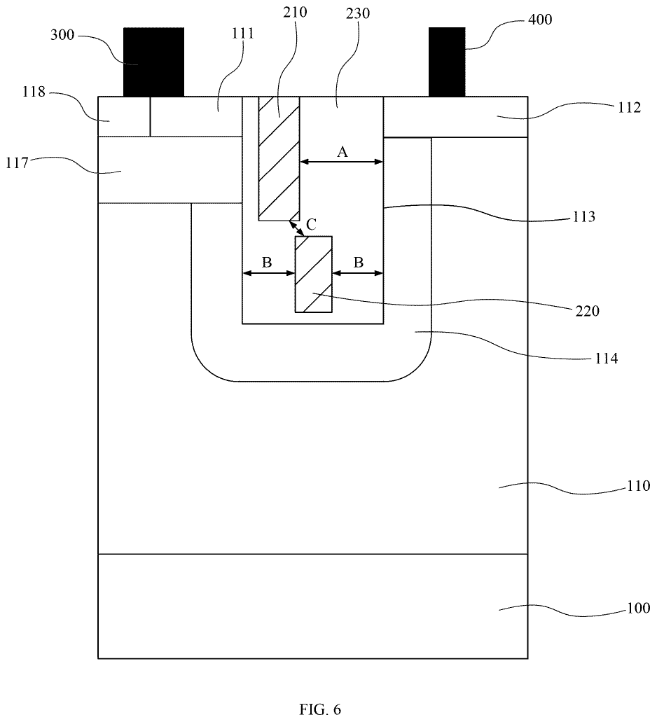

The BV of the power semiconductor device can be adjusted by modifying the respective depths of main gate 210 and shielding gate 220, as well as the spacing between main gate 210 and shielding gate 220 (e.g., adjusting Interval C as shown in FIG. 6). In one example, contact holes can be formed in insulating layer 230, with the ends of the contact holes extending to shielding gate 220, thus allowing shielding gate 220 to be connected to an external potential through the contact holes. The interleaved arrangement of main gate 210 and shielding gate 220 within gate trench 113 can enable voltage tunability of the power semiconductor device. For example, when the power semiconductor device is in an off state, shielding gate 220 can be connected to a 0V potential. And, when the power semiconductor device is in an on state, shielding gate 220 can be connected to either a fixed 0V potential or a fixed potential greater than 0V, thereby reducing the device's Rsp.

The interleaved configuration of main gate 210 and shielding gate 220 within gate trench 113 may also help reduce capacitive coupling between main gate 210 and drain region 400. Shielding gate 220 can modify the electric field distribution around main gate 210, thereby reducing the electric field intensity in the vicinity of drain 400. As a result, the gate-to-drain charge (Qgd) of the power semiconductor device may be significantly reduced. As another example, for low-rated-voltage semiconductor devices (e.g., those rated at 40V or below), the increased drift length along the perimeter of gate trench 113 may result in a relatively shallow trench depth. In this case, shielding gate 220 can be merged with main gate 210, or omitted altogether depending on target application requirements.

As shown in FIGS. 5-8, shielding gate 220 may be spaced apart from the first inner wall of gate trench 113 by a first spacing, and spaced apart from the second inner wall of gate trench 113 by a second spacing. The first spacing can be equal to the second spacing (e.g., both being represented as Spacing B in FIG. 6). That is, in a width direction of gate trench 113, shielding gate 220 may be located in the middle of gate trench 113, and regions of insulating layer 230 located on both sides of shielding gate 220 can be used as voltage-withstanding regions.

The first and second spacings can be adjusted according to requirements of the shielding field regions. In one example manufacturing process of the power semiconductor device, gate trench 113 can be filled to form insulating layer 230, a groove may be provided in the middle area of insulating layer 230, and shielding gate 220 can be formed in the groove. For example, shielding gate 220 may be disposed in a middle position along the width direction of gate trench 113, such that the groove is provided on insulating layer 230, thereby facilitating the formation of shielding gate 220 in insulating layer 230, and improving the processing efficiency of the power semiconductor device.

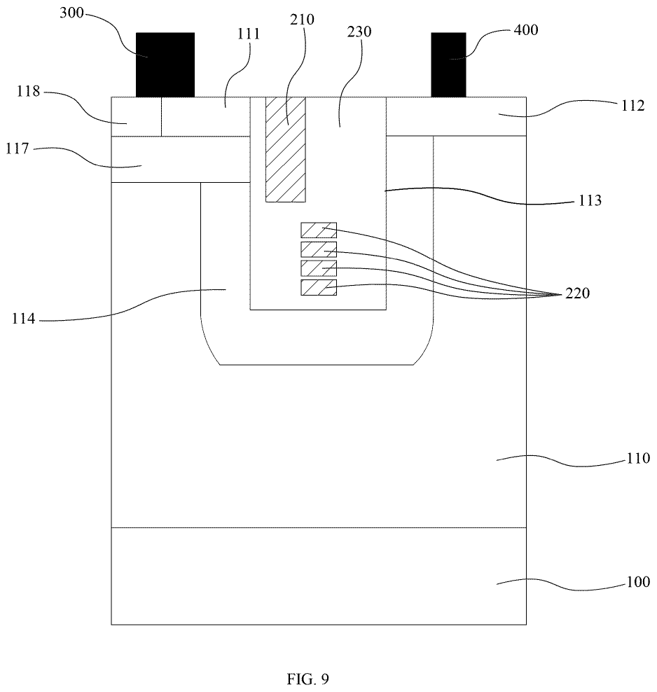

Referring now to FIG. 9, shown is a cross-section diagram of a sixth example power semiconductor device, in accordance with embodiments of the present invention. In this particular example, the power semiconductor device can include two or more shielding gates 220, which can be arranged at intervals along a thickness direction of substrate 100. In an example manufacturing process of the power semiconductor device, the length of each shielding gate 220 and the spacing between adjacent shielding gates 220 can be set according to the target BV and the gate-drain charges. The lengths of shielding gates 220 may be the same or different. Each of shielding gates 220 can be disposed below main gate 210, and situated on the side of main gate 210 closer to drain region 112. Through the above arrangements, the universality of the power semiconductor device may be enhanced, and the target BV and the gate-drain charges of the power semiconductor device can be selectively tuned by adjusting the quantity of shielding gates 220, the length of each shielding gate 220, and the spacing between the adjacent shielding gates 220.

As shown in FIGS. 3 and 5-12, active region 110 can also include body region 117 of a second doping type. Body region 117 can be located at a bottom of source region 111, and a side edge of body region 117 and a side edge of source region 111 may form part of the first inner wall of gate trench 113. The gate oxide can be in contact with the source region and body region 117. The ion doping types of body region 117 and source region 111 can be different. When the power semiconductor device is an NLDMOS, P-type impurities can be doped in body region 117. And, when the power semiconductor device is a PLDMOS, N-type impurities may be doped in body region 117. For example, active region 110 can also include doped region 114, and a first end of doped region 114 away from drain region 112 can connect to body region 117. For example, active region 110 can also include doped region 115, and a first end of doped region 115 away from drain region 112 can connect to body region 117. For example, an ion doping concentration of body region 117 can be greater than an ion doping concentration of doped region 115.

As shown in FIGS. 3 and 5-12, active region 110 can also include body contact region 118, where body contact region 118 and source region 111 can be arranged side by side. Ion doping types of body contact region 118 and body region 117 may be the same, and an ion doping concentration of body contact region 118 can be greater than the ion doping concentration of body region 117. For example, doped region 114 may be of the first doping type, and doped region 114 can surround sidewalls and a bottom of gate trench 113.

Ion doping types of source region 111, drain region 112, and doped region 114 can be the same. When the power semiconductor device is an NLDMOS, N-type impurities may be doped in doped region 114. And, when the power semiconductor device is a PLDMOS, P-type impurities can be doped in doped region 114. Doped region 114 can be formed by chain implantation. For example, an ion doping concentration of doped region 114 can be less than an ion doping concentration of drain region 112, and greater than an ion doping concentration of active region 110. The first end of doped region 114 can be electrically connected to body contact region 118 through body region 117. For example, doped region 114 may form a U-shaped region surrounding gate trench 113, and a width of doped region 114 can be adjusted as required. Doped region 114 may form at least part of the drift region. By providing doped region 114, the ion doping concentration of the drift region between source region 111 and drain region 112 can be increased, and the Rsp of the power semiconductor device reduced.

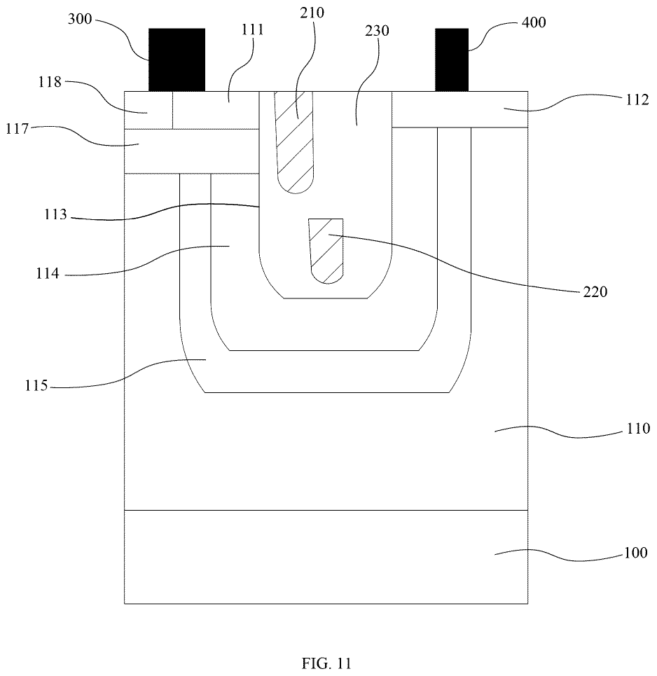

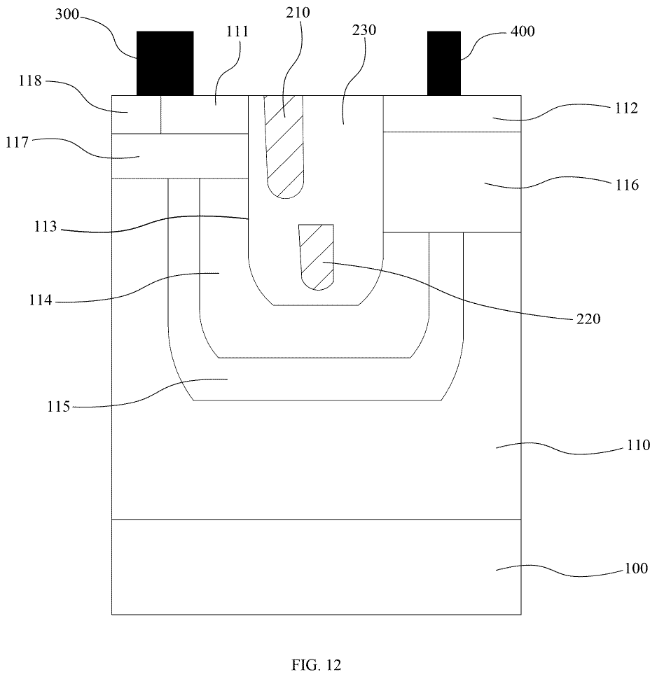

As shown in FIGS. 11 and 12, doped region 115 can be of the second doping type, and doped region 115 may surround a sidewall and a bottom of doped region 114. Ion doping types of doped region 114 and doped region 115 can be different. When the power semiconductor device is an NLDMOS, P-type impurities may be doped in doped region 115. And, when the power semiconductor device is a PLDMOS, N-type impurities can be doped in doped region 115. Doped region 115 can be formed by chain implantation. FIGS. 11 and 12 show that the first end of doped region 115 can be electrically connected to body contact region 118 through body region 117. For example, doped region 115 may form a U-shaped region surrounding doped region 114, and a width of doped region 115 can be adjusted as required. By disposing doped region 115, doped regions 114 and 115 may be mutually depleted, and the power semiconductor device can implement dual reduced-surface-field (RESURF) and increase BV of the power semiconductor device.

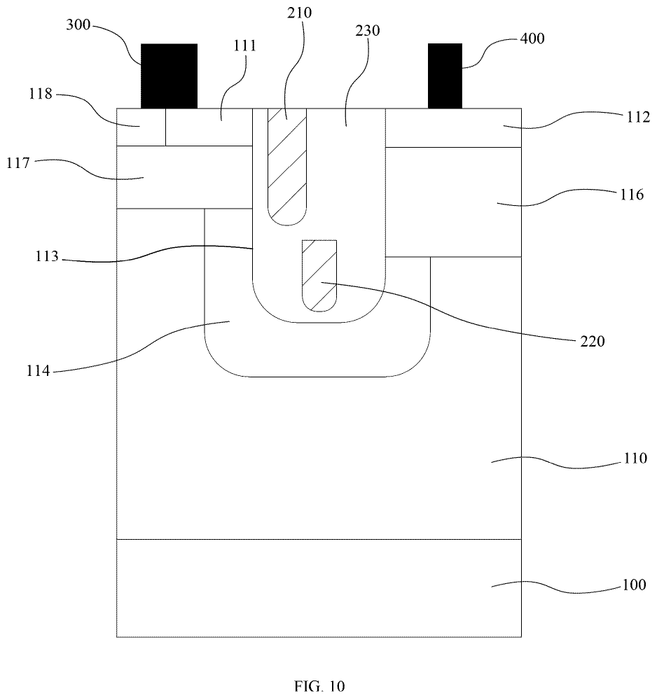

As shown in FIGS. 10 and 12, active region 110 can also include heavily doped buffer region 116 of the first doping type. Heavily doped buffer region 116 can be located at a bottom of drain region 112, and an ion doping concentration of heavily doped buffer region 116 may be less than the ion doping concentration of drain region 112. Heavily doped buffer region 116 can form a drain drift region by doping ion implantation and/or thermal diffusion, and for the NLDMOS, an N-type drain drift region (NDD) can be formed. FIGS. 10 and 12 illustrate that a side surface of heavily doped buffer region 116 can be contact with gate trench 113. The depth of heavily doped buffer region 116 can be adjusted as needed. For example, a second end of doped region 114 and/or a second end of doped region 115 can connect to a bottom of heavily doped buffer region 116.

By providing heavily doped buffer region 116, when the power semiconductor device bears a high voltage, a relatively uniform electric field distribution can be formed in heavily doped buffer region 116, thereby mitigating the risk of breakdown due to electric field concentration. Further, heavily doped buffer region 116 may possess reduced resistivity, thereby decreasing the impedance encountered by the current of drain 400 along the internal conduction path of the power semiconductor device and contributing to a reduction in the device's Rsp.

For example, body region 117 can form a PN junction with active region 110 and/or with doped region 114. The side edge of body region 117 and the side edge of source region 111 may form part of the first inner wall of gate trench 113, such that when the power semiconductor device is forward biased, the accumulated charge in the PN junction may be confined along the sidewall of gate trench 113. In addition, both the distance between gate trenches 113, and the width of gate trenches 113, may be less than the distance between source 300 and drain 400 in conventional power semiconductor devices. This configuration may restrict carrier movement to a narrower drift region, thereby facilitating efficient carrier recombination during reverse recovery and resulting in a reduced reverse recovery charge (Qrr). For low Qrr power semiconductor devices, reverse recovery current and switching power losses can be reduced.

When active region 110 includes doped region 114 and the side edge of body region 117 forms part of the sidewall of gate trench 113, the area occupied by the PN junction can be limited to the region of the bottom of body region 117 connected to doped region 114. Also, the area of the PN junction can be narrowed due to the scaling of the advanced process node, which may further reduce the reverse recovery current and the switching power losses. Further, a channel can be formed at the side edge of body region 117 facing gate trench 113, resulting in a vertical or quasi-longitudinal channel structure within the power semiconductor device, which may reduce the lateral dimensions of the device, thereby allowing for a smaller cell pitch and improved integration density.

The channel of the power semiconductor device of particular embodiments can be precisely controlled. For example, by employing advanced process implantation tools, such as an injection platform compatible with a 55 nm process node, utilizing longitudinal ion implantation, and leveraging the implantation energy differential between body region 117 and source region 111, the ion implantation energy along the longitudinal direction can be accurately regulated. As compared with approaches whereby the body region and source region are formed through double diffusion, the channel can be effectively shortened in certain embodiments. The power semiconductor device of particular embodiments may exhibit a lower gate-to-source charge (Qgs) and a reduced channel length, thereby enhancing its suitability for operation at high frequencies.

Particular embodiments also provide a method of making a power semiconductor device that can include providing substrate 100 (a P-type substrate or an N-type substrate), and an epitaxial layer may or may not be formed on substrate 100. The method can also include forming active region 110 in substrate 100, where, e.g., active region 110 is formed by ion implantation. The method can also include recessing an upper surface of substrate 100 to active region 110 to form gate trench 113, where, e.g., gate trench 113 can be formed in substrate 100 by heat treatment and/or etching process. The method can also include filling gate trench 113 to form insulating layer 230 (e.g., silicon dioxide). The method can also include forming main gate 210 in insulating layer 230, wherein as an example, where main gate 210 may extend from an upper surface of gate trench 113 into an interior of gate trench 113. For example, after insulating layer 230 is formed, a part of insulating layer 230 can be removed by photolithography to form a groove. An opening of the groove may be located on the upper surface of substrate 100, and main gate 210 can be formed in the groove and situated on the side of gate trench 113 that is closer to source region 111.

The method can also include forming source region 111 and drain region 112 on an upper surface of active region 110. For example, gate trench 113 can be disposed between source region 111 and drain region 112. For example, source region 111 and drain region 112 can be formed by an ion implantation process or ion implantation heating diffusion process, and the ion doping concentrations of source region 111 and drain region 112 can each be greater than the ion doping concentration of active region 110. In this way, the drift region length may be transformed from the lateral spacing between the source and drain regions to the perimeter of the gate trench. This structural shift can reduce the device's lateral dimension while maintaining the target BV, and lowering the specific on-resistance (Rsp), thereby resulting in an improved BV-to-Rsp trade-off and enabling a more compact device design.

For example, before forming main gate 210 in insulating layer 230, the method can also include forming at least one shielding gate 220 in insulating layer 230. Shielding gate 220 may be disposed below main gate 210, and shielding gate 220 and main gate 210 can be spaced apart from each other. Shielding gate 220 can be disposed at a side of main gate 210 closer to drain region 112. For example, a portion of insulating layer 230 may be formed by partially filing gate trench 113. A first groove may then be formed within the portion of insulating layer 230, and shielding gate 220 can be formed in the first groove. After shielding gate 220 is formed, the remaining portion of gate trench 113 may be further filled to form an additional section of insulating layer 230. A second groove can be subsequently formed in this newly added portion of insulating layer 230, and main gate 210 may be formed within the second groove.

The interleaved arrangement of main gate 210 and shielding gate 220 within gate trench 113 can enable voltage tunability of the power semiconductor device, while also contributing to a reduction in the device's Qgd. For example, main gate 210 can be arranged at a location closer to source region 111 than to drain region 112. For example, the inner wall of gate trench 113 can include a first inner wall positioned closer to source region 111 and a second inner wall positioned closer to drain region 112. Distance A between main gate 210 and the second inner wall of gate trench 113 can be greater than the distance between main gate 210 and the first inner wall of gate trench 113.

Distance A can be determined according to the requirements of the device electric field distribution, the second groove may be determined based on Distance A, and main gate 210 can be formed within the second groove. Within gate trench 113, main gate 210 may be positioned closer to source region 111 than to drain region 112, which may enhance switching characteristics, reduce on-resistance, and help to minimize parasitic capacitance between main gate 210 and drain region 112. For example, the method can also include forming source electrode 300 on the upper surface of substrate 100, and source electrode 300 can be electrically connected to source region 111. For example, the method can also include forming drain electrode 400 on the upper surface of substrate 100, and drain electrode 400 can be electrically connected to drain region 112.

For example, a first metal layer may be deposited at a position corresponding to source region 111 on the upper surface of substrate 100 as source electrode 300. Also, a second metal layer can be deposited at a position corresponding to drain region 112 on the upper surface of substrate 100 as drain electrode 400. Source electrode 300 may be electrically connected to source region 111, and drain electrode 400 electrically connected to drain region 112. The power semiconductor device can be connected to external circuitry through source electrode 300 and drain electrode 400.

For example, after forming gate trench 113 and before forming source region 111 and drain region 112, the method can also include forming doped region 114 in active region 110, where doped region 114 surrounds sidewalls and a bottom of gate trench 113. An ion doping concentration of doped region 114 can be greater than an ion doping concentration of active region 110. Active region 110 may be of the first doping type. Doped region 114 can be formed by chain implantation, and doped region 114 can connect to source region 111 and/or drain region 112. By providing doped region 114, the ion doping concentration of the drift region between source region 111 and drain region 112 can be increased, and the Rsp of the power semiconductor device reduced.

For example, before forming doped region 114, the method can also include forming doped region 115 in active region 110. Doped region 115 may surround sidewalls and a bottom of doped region 114. Ion doping types of doped region 114 and doped region 115 can be different. Doped region 115 may enhance the ion doping concentration of doped region 114, resulting in a first doped region 114 with increased ion doping concentration. For example, because doped region 115 is formed prior to the formation of doped region 114, the ion doping concentration of doped region 114 that incorporates doped region 115 can be greater than that of a first doped region 114 formed without doped region 115. Doped region 115 can be formed by chain implantation, and after the formation of doped region 115, the chain implantation can again be performed to form doped region 114. Ion doping types of doped regions 114 and 115 may be different. Doped region 115 can surround the sidewalls and the bottom of doped region 114. By disposing doped region 115, doped regions 114 and 115 can be mutually depleted, and the power semiconductor device can implement dual RESURF and increase BV of the power semiconductor device.

The method can also include forming heavily doped buffer region 116 in active region 110. An ion doping concentration of heavily doped buffer region 116 can be lower than an ion doping concentration of drain region 112, and drain region 112 can be disposed in heavily doped buffer region 116. In one case, heavily doped buffer region 116 can be formed by ion implantation process or an ion implantation heating diffusion process. Ion doping types of heavily doped buffer region 116 and drain region 112 can be the same. After drain region 112 is formed in active region 110, the ion doping concentration of heavily doped buffer region 116 can be lower than the ion doping concentration of drain region 112.

By providing heavily doped buffer region 116, when the power semiconductor device bears a high voltage, a relatively uniform electric field distribution can be formed in heavily doped buffer region 116, thereby mitigating the risk of breakdown due to electric field concentration. Further, heavily doped buffer region 116 can possess reduced resistivity, thereby decreasing the impedance encountered by the current of the drain 400 along the internal conduction path of the power semiconductor device and contributing to a reduction in the device's Rsp.

For example, the method can also include forming body region 117 in active region 110. Body region 117 can be located at a bottom of source region 111, and a side edge of body region 117 and a side edge of source region 111 may form part of a first inner wall of gate trench 113 positioned closer to source region 111. Body region 117 can be formed by ion implantation or ion implantation heating diffusion. After gate trench 113 is formed in substrate 100, the sidewall of gate trench 113 can connect to body region 117 and source region 111, such that the side edge of body region 117 and the side edge of source region 111 form the part of the sidewall of gate trench 113 positioned closer to source region 111. When the power semiconductor device is provided with doped region 115, an ion doping concentration of body region 117 can be greater than an ion doping concentration of doped region 115.

For example, a PN junction can be formed between body region 117 and active region 110, and/or between body region 117 and doped region 114. The side edge of body region 117 and the side edge of source region 111 may form part of the first inner wall of gate trench 113, such that when the power semiconductor device is forward biased, the accumulated charge in the PN junction can be confined along the sidewall of gate trench 113. Additionally, both the distance between the device and gate trench 113, and the width of gate trench 113, can be less than the distance between source 300 and drain 400 in other power semiconductor devices. This configuration may restrict carrier movement to a narrower drift region, thereby facilitating efficient carrier recombination during reverse recovery and resulting in a reduced Qrr. For low Qrr power semiconductor devices, reverse recovery current can be reduced and switching power losses can be reduced. When active region 110 includes doped region 114 and the side edge of body region 117 forms part of the sidewall of gate trench 113, the area occupied by the PN junction may be limited to the region of the bottom of body region 117 connected to doped region 114, and the area of the PN junction can be narrowed due to the scaling of the advanced process node, which may further reduce the reverse recovery current and reduce the switching power losses.

A channel can be formed at the side edge of body region 117 facing gate trench 113, resulting in a vertical or quasi-longitudinal channel structure within the power semiconductor device, which can enable a reduction in the lateral dimensions of the device, thereby allowing for a smaller cell pitch and improved integration density. In particular embodiments, body region 117 can be formed by ion implantation or ion implantation heating diffusion, and a gate-to-source charge of the power semiconductor device may be reduced by adjusting a depth of body region 117 disposed below source region 111. For example, body region 117 can be formed by ion implantation using an injection platform compatible with, e.g., a 55 nm process node, thereby achieving enhanced control precision. The depth of body region 117 can be precisely controlled, thus allowing the overlap area between gate trench 113 and body region 117 beyond source region 111 to be adjustable. This arrangement can enable the Qgs and the channel of the power semiconductor device to be minimized, thereby facilitating optimal performance of the device at high frequencies.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A power semiconductor device, comprising:
a) a substrate, comprising an active region having a source region and a drain region each of a first doping type and extending from an upper surface of the substrate into an interior thereof;
b) a gate trench, formed between the source region and the drain region and being recessed from the upper surface of the substrate to the active region;
c) a main gate located in the gate trench, wherein the main gate extends downward from an upper surface of the gate trench; and
d) an insulating layer, formed between an inner wall of the gate trench and the main gate.

2. The power semiconductor device of claim 1, wherein the main gate is arranged at a location closer to the source region than to the drain region.

3. The power semiconductor device of claim 1, further comprising:
a) a source electrode, disposed on the upper surface of the substrate and electrically connected to the source region; and
b) a drain electrode, disposed on the upper surface of the substrate and electrically connected to the drain region.

4. The power semiconductor device of claim 1, further comprising at least one shielding gate disposed in the gate trench, disposed below the main gate, being spaced apart from the main gate, and disposed at a side of the main gate closer to the drain region.

5. The power semiconductor device of claim 4, wherein:
the inner wall of the gate trench comprises a first inner wall positioned closer to the source region and a second inner wall positioned closer to the drain region;
b) the shielding gate is spaced apart from the first inner wall by a first spacing, and
spaced apart from the second inner wall by a second spacing; and
c) the first spacing is equal to the second spacing.

6. The power semiconductor device of claim 4, further comprising two or more shielding gates that are arranged at intervals along a thickness direction of the substrate.

7. The power semiconductor device of claim 1, wherein the active region further comprises a first doped region of the first doping type, wherein the first doped region surrounds sidewalls and a bottom of the gate trench.

8. The power semiconductor device of claim 7, wherein the active region further comprises a second doped region of a second doping type, wherein the second doped region surrounds a sidewall and a bottom of the first doped region.

9. The power semiconductor device of claim 1, wherein the active region further comprises a heavily doped buffer region of the first doping type, wherein the heavily doped buffer region is located at a bottom of the drain region, and an ion doping concentration of the heavily doped buffer region is lower than an ion doping concentration of the drain region.

10. The power semiconductor device of claim 1, wherein the active region further comprises a body region of a second doping type, wherein the body region is located at a bottom of the source region, and a side edge of the body region and a side edge of the source region constitute part of the first inner wall of the gate trench.

11. The power semiconductor device of claim 1, wherein a cross section of the gate trench is U-shaped, rectangular, or trapezoidal.

12. A method of making a power semiconductor device, the method comprising:
a) providing a substrate;
b) forming an active region in the substrate;
c) recessing an upper surface of the substrate to the active region to form a gate trench;
d) filling the gate trench to form an insulating layer;
e) forming a main gate in the insulating layer, wherein the main gate extends from an upper surface of the gate trench into an interior of the gate trench; and
f) forming a source region and a drain region extending from an upper surface of the active region into its interior, wherein the gate trench is disposed between the source region and the drain region.

13. The method of claim 12, wherein before forming the main gate in the insulating layer, the method further comprises:
a) forming at least one shielding gate in the insulating layer;
b) wherein the shielding gate is disposed below the main gate, and the shielding gate and the main gate are spaced apart; and
c) wherein the shielding gate is disposed at a side of the main gate closer to the drain region.

14. The method of claim 12, wherein the main gate is arranged at a location closer to the source region than to the drain region.

15. The method of claim 12, further comprising:
a) forming a source electrode on the upper surface of the substrate, wherein the source electrode is electrically connected to the source region; and
b) forming a drain electrode on the upper surface of the substrate, wherein the drain electrode is electrically connected to the drain region.

16. The method of claim 12, wherein after forming the gate trench and before forming the source region and the drain region, the method further comprises forming a first doped region in the active region, wherein the first doped region surrounds a sidewall and a bottom of the gate trench, and an doping concentration of the first doped region is greater than an doping concentration of the active region, wherein the active region is of a first doping type.

17. The method of claim 16, wherein before forming the first doped region, the method further comprises forming a second doped region in the active region, wherein the second doped region surrounds a sidewall and a bottom of the first doped region, wherein doping types of the first doped region and the second doped region are different.

18. The method of claim 12, further comprising forming a heavily doped buffer region in the active region, wherein an ion doping concentration of the heavily doped buffer region is lower than an ion doping concentration of the drain region, and the drain region is disposed in the heavily doped buffer region.

19. The method of claim 12, further comprising forming a body region in the active region, wherein the body region is located at a bottom of the source region, and a side edge of the body region and a side edge of the source region form part of a first inner wall of the gate trench positioned closer to the source region.

20. The method of claim 19, wherein the body region is formed by ion implantation or ion implantation heating diffusion, and a gate-to-source charge of the power semiconductor device is reduced by adjusting a depth of the body region disposed beneath the source region.
